(19) United States
(12) Patent Application Publication
(10) Pub. No.: US 2009/0114425 A1
(43) Pub. Date: May 7, 2009

(54) CONDUCTIVE PASTE AND PRINTED CIRCUIT BOARD USING THE SAME

(75) Inventors: Eung-Suek LEE, Ansan-si (KR); Seung-Hyun BAIK, Seoul (KR); Young-Jin KIM, Seoul (KR); Young-Seok OH, Suwon-si (KR); Jae-Boong CHOI, Yongin-si (KR); Dae-Woo SUH, Seoul (KR); Je-Gwang YOO, Yongin-si (KR); Chang-Sup RYU, Yongin-si (KR); Jun-Oh HWANG, Nam-gu (KR); Jee-Soo MOK, Yongin-si (KR)

Correspondence Address: MCDERMOTT WILL & EMERY LLP, 600 13TH STREET, N.W., WASHINGTON, DC, 20005-3096, US

(73) Assignees: SAMSUNG ELECTRO-MECHANICS CO., LTD.; SUNGKYUNKWAN UNIVERSITY

(21) Appl. No.: 12/178,285

(22) Filed: Jul. 23, 2008

(30) Foreign Application Priority Data
Nov. 7, 2007 (KR) 10-2007-0113437

(51) Int. Cl. H05K 1/00; H01B 1/14

(52) U.S. Cl. 174/250; 252/502; 252/506; 977/742

(57) ABSTRACT

A conductive paste and a printed circuit board using the conductive paste are disclosed. The conductive paste including conductive particles and carbon nanotubes according to the invention, can improve an electrical conductivity of the conductive paste.

### CROSS-REFERENCE TO RELATED APPLICATION

This application claims the benefit of Korean Patent Application No. 10-2007-0113437 filed with the Korean Intellectual Property Office on Nov. 7, 2007, the disclosure of which is incorporated herein by reference in its entirety.

### BACKGROUND

1. Technical Field

The present invention relates to a conductive paste and a printed circuit board using the conductive paste.

2. Description of the Related Art

In step with the development of electro-components, there is a need for improving the performance of HDI (high density interconnection) boards having fine pitch wiring. This may involve interconnecting different layers of circuit patterns and increasing the degree of freedom in design.

According to the related art, a method of manufacturing a printed circuit board includes forming a plating layer by drilling, chemical copper plating, and/or electrolytic copper plating, and then forming a desired number of circuit layers by laminating process after forming a circuit layer. However, such a conventional method of manufacturing a multi layer printed circuit board cannot satisfy the demands for low cost resulted from a downward trend of products such as cell phones in which this manufacturing method is applied and reduction of lead-time. As such, there is a need for a new process to resolve these problems.

Conductive pastes to interconnect layers have been widely used to solve these problems. However, when the conductive paste is used to interconnect layer, the specific resistance becomes greater, the adhesion to a copper film becomes weaker, and the thermal conductivity is deteriorated due to a polymer component included in the conductive paste than when the copper plating is used.

### SUMMARY

An aspect of the invention is to provide a conductive paste and a printed circuit board using the conductive paste to improve the electrical conductivity.

One aspect of the invention provides a conductive paste including conductive particles; carbon nanotubes and a binder.

The surface of carbon nanotubes may be coated with metal particles. Specifically, the metal particles can be selected from the group consisting of silver, copper, tin, indium, nickel, palladium, and mixtures thereof.

In one embodiment of the invention, the conductive paste includes 70 to 90 parts by weight of the conductive particles, 0.5 to 15 parts by weight of the carbon nanotubes, and 1 to 15 parts by weight of the binder, per 100 parts by weight of the conductive paste.

The carbon nanotubes may be selected from the group consisting of single-walled carbon nanotubes, multi-walled carbon nanotubes and mixtures thereof.

The conductive particles may be selected from the group consisting of silver, copper, tin, indium, nickel and mixtures thereof.

The conductive paste has a specific resistance of about 5.0×10⁻⁴ to 3.0×10⁻⁶ Ω·cm after curing at a temperature range of about 140 to 200° C.

Another aspect of the invention provides a printed circuit board including a plurality of substrates; an insulation layer placed between the substrates; and a conductive paste bump penetrating the insulation layer and interconnecting the substrates, wherein the conductive paste bump includes conductive particles, carbon nanotubes, and a binder.

### BRIEF DESCRIPTION OF THE DRAWINGS

FIG. 1 is a SEM (scanning electron microscope) image of a carbon nanotube coated with silver.

FIG. 2 is a SEM image of a carbon nanotube coated with nickel.

FIG. 3 is a SEM image of a carbon nanotube coated with palladium.

FIG. 4 is a SEM image of a bridge between the conductive paste including silver particles and silver-coated carbon nanotubes, and the silver-coated carbon nanotubes.

FIG. 5 is a cross-sectional view of a printed circuit board according to an embodiment of the invention,

### DETAILED DESCRIPTION

Metal pastes is currently widely used as a conductive paste. The metal paste includes metal powders and a binder composed of a epoxy-melamine resin. The metal conductive paste has a specific resistance of about 10⁻⁴ Ω·cm after curing, and has a price higher than bulk metals. Also, the metal conductive paste cannot be suitable for forming microcircuits. Since the epoxy-melamine resin, which is a non-conductive material, is filled in the metal conductive paste, it may be an interfering factor for electrons to flow through the paste.

Carbon nanotubes provide superb electrical properties, as shown in the following Table 1.

TABLE 1

| | Carbon | |
|---|---|---|
| Physical Property | Nanotubes | Comparative Materials |
| Density | 1.33-1.40 g/cm³ | 2.7 g/cm³ (Aluminum) |
| Current Density | 1 × 10⁹ A/cm² | 1 × 10⁶ A/cm² |
| | | (Copper Cable) |
| Thermal Conductivity | 6000 W/mk | 400 W/mk (Copper) |
| Specific Resistance | 1 × 10⁻¹⁰ Ω · cm | 1.72 × 10⁻⁶ Ω · cm (Copper) |

As show in Table 1, carbon nanotubes have theoretically better electrical properties compared to copper and aluminum which show relatively good electrical conductivity and resistivity. Therefore, the carbon nanotubes may decrease electrical resistance when used for interconnecting layers as a material for the conductive paste. Moreover, the carbon nanotubes also provide good thermal conductivity, so that heat inside a printed circuit board can be dissipated out easily.

In detail, the carbon nanotubes may be used by mixing with conductive particles and a binder. The carbon nanotubes make electrical bridges between the conductive particles when the carbon nanotubes are mixed with the conductive particles.

Further, to improve a property of interfacial bonding between the conductive pastes and the carbon nanotubes, the surface of carbon nanotubes may be coated with metal particles.

The metal particles coated on the carbon nanotubes may be selected from the group consisting of silver, copper, tin, indium, nickel, palladium, and mixtures thereof, but is not thus limited. Among them, silver may be more preferably used.

According to one embodiment of the invention, the carbon nanotubes coated with silver may be prepared as follow: The carbon nanotubes are treated with in the mixture of H₂SO₄ and HNO₃. These treated carbon nanotubes have low chemical reactivity, so that it is difficult to deposit the metal particles on the carbon nanotubes. To solve the problem, the treated carbon nanotubes are immersed in solution of SnCl₂—HCl, followed by being immersed in solution of PdCl₂—HCl. As a consequence of the process, Sn²⁺ ions are deposited on the surface of the carbon nanotube, Pd²⁺ ions are reduced to Pd by Sn²⁺, and these Pd particles are deposited on the surface of the carbon nanotubes. Here, when AgNO₃ solution is plated, Pd particles reduce silver ions to neutral silver particles which are then coated on the surface of the carbon nanotubes.

According to another embodiment of the invention, after the carbon nanotubes are immersed in the mixture of H₂SO₄ and HNO₃ and an ultra-sonication is accomplished, they are washed with distilled water. Then, the carbon nanotubes are immersed in a mixture of formaldehyde (HCHO), ethanol and water which are mixed in an appropriate ratio When the mixture solution of the carbon nanotubes is added to a solution of AgNO₃ 10 kg/m³ of pH 8.5, silver ions are reduced to silver particles, so that silver particles are coated on the carbon nanotubes.

The conductive particles of the invention may be selected from the group consisting of silver, copper, tin, indium, nickel and mixtures thereof, but is not thus limited. Among them, silver particles may be more preferably used.

The binder of the invention may be a phenol resin or a epoxy resin, which is well known in the art.

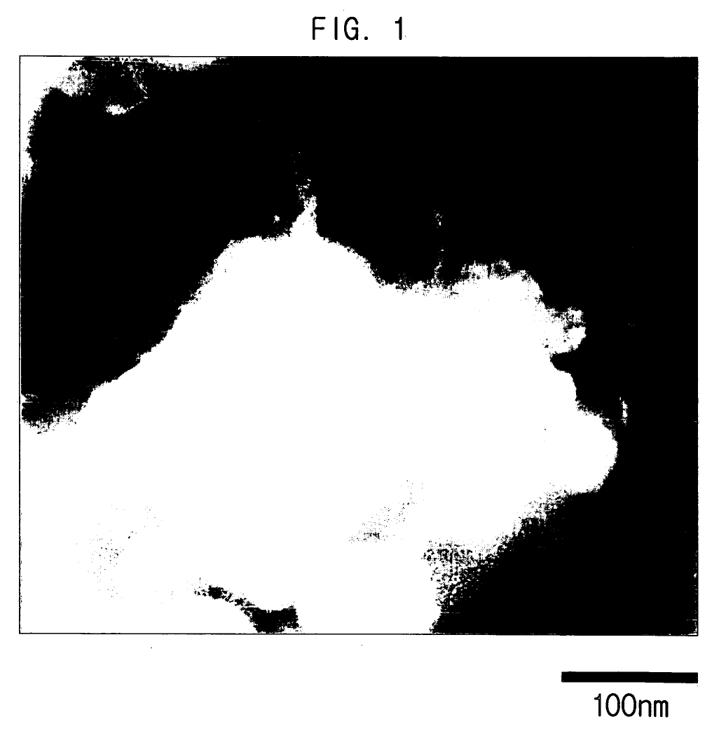

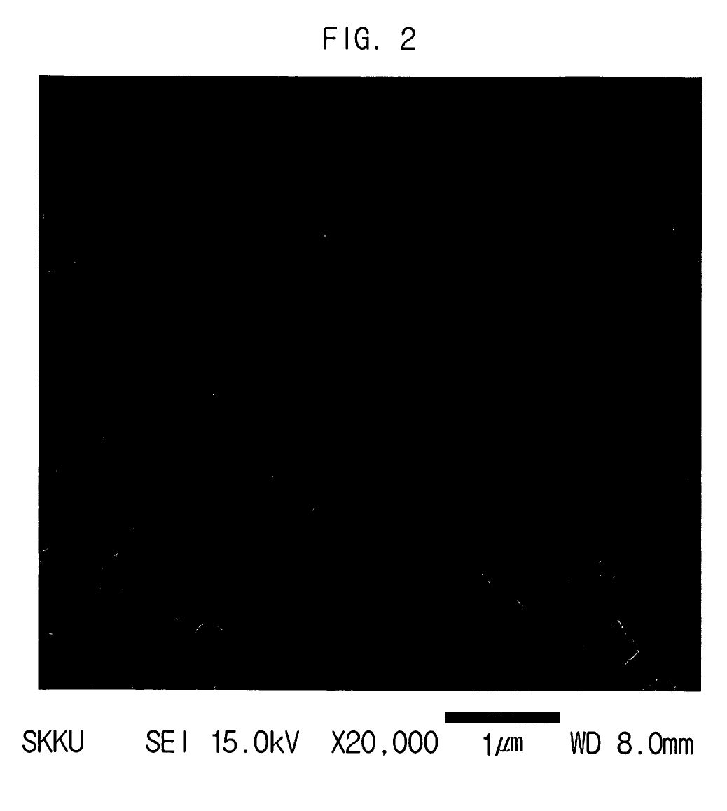

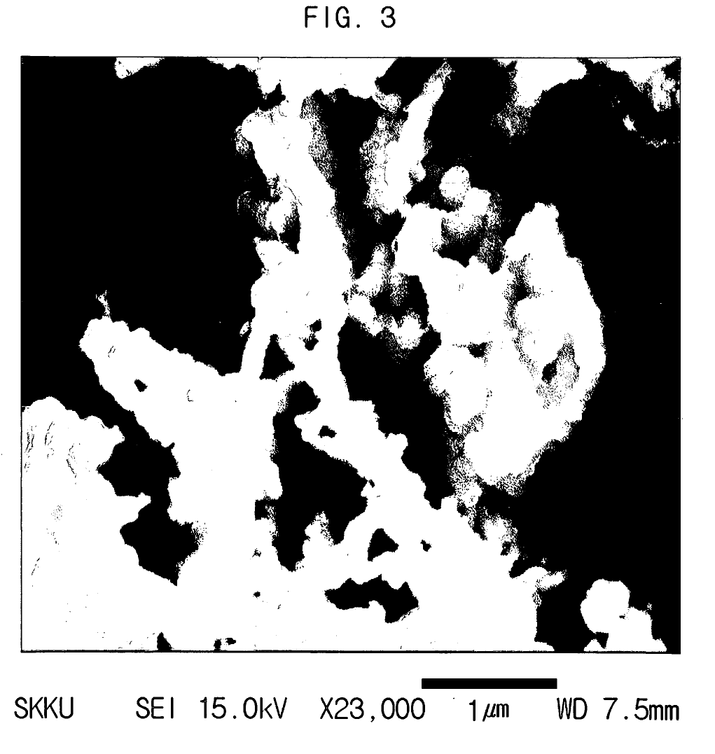

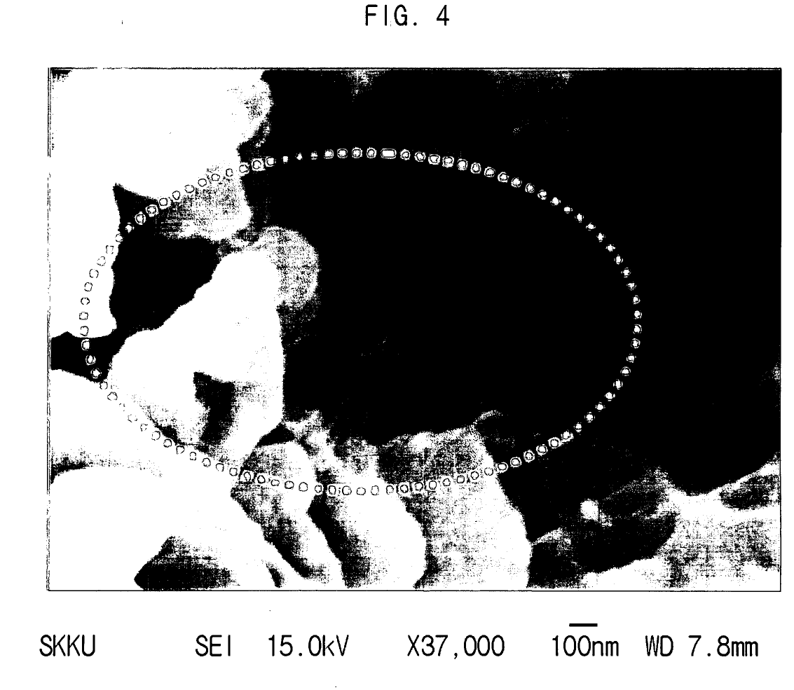

FIGS. 1 to 3, show SEM images of the carbon nanotubes coated with silver, nickel and palladium, respectively. FIG. 4 is a SEM image of a bridge between a conductive paste including silver particles and carbon nanotubes coated with silver, and the carbon nanotubes coated with silver.

In certain embodiments of the invention, the conductive paste may include 70 to 90 parts by weight of the conductive particles, 0.5 to 15 parts by weight of the carbon nanotubes, and 1 to 15 parts by weight of the binder per 100 parts by the weight of the conductive paste. If the content of the carbon nanotubes is less then than 0.5 parts by weight, a desired specific resistance of the conductive paste may not be obtained (Percolation theory). On the other hand, if the content of the carbon nanotubes exceeds 15 parts by weight, holes may be blocked or some other errors may occur in the printing operation.

Also, in certain embodiments of the invention, the carbon nanotubes may be single-walled nanotubes or multi-walled nanotubes.

In certain embodiments of the invention, the conductive paste is cured at a temperature range of about 140 to 200° C., and a specific resistance of the conductive paste after curing is less than or equal to 5.0×10⁻⁴ to 3.0×10⁻⁶ Ω·cm, and more preferable is less than or equal to 3.35×10⁻⁵ Ω·cm. When a conductive paste has a specific resistance similar to that of metal (for example, a specific resistance of silver is 1.6×10⁻⁶ Ω·cm), electrical properties, such as signal transmission efficiency and/or heat generation are improved. Therefore, the conductive paste of the invention having a low specific resistance shows good electrical conductivity.

In certain embodiments of the invention, the conductive paste further contains a curing agent which is well known in this art.

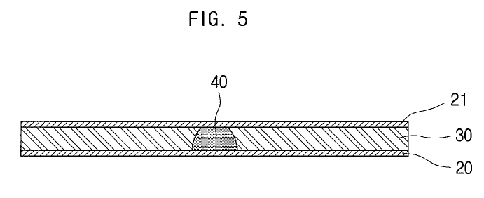

Another aspect of the invention is to provide a printed circuit board using the conductive paste of the present invention. In particular, as shown in FIG. 5, the present invention provides a printed circuit board including a plurality of substrates 20 and 21; an insulation layer 30 placed between the substrates; and a conductive paste bump 40 penetrating the insulation layer and interconnecting the substrates, wherein the conductive paste bump includes conductive particles, carbon nanotubes, and a binder.

Here, the substrate 20 and substrate 21 of FIG. 5 are illustrated, so that the embodiment of the invention can be described for a very simple structure. It is to be appreciated that more than two substrates can be used to implement a multi-layered printed circuit board.

The conductive paste bump 40 that interconnects the substrates 20, 21 may be made of a conductive particles, carbon nanotubes and a binder. The substrates 20, 21 in which the bump 40 for the interlayer connection is formed, can be formed by performing a B2it (Buried bump interconnection technology) process.

The invention may be better understood by reference to the following examples which are intended for the purpose of illustration and are not to be construed as in any way limiting the scope of the present invention, which is defined in the claims appended hereto.

### EXAMPLES

### Example 1

The single-walled carbon nanotubes (SWNTs) having a diameter of 0.7 to 1.1 nm and an average length of 1 μm, which were produced by the HiPco method, were immersed in the mixture of H₂SO₄ and HNO₃ (1:3) at 120° C. for 10 hours. The carbon nanotubes were washed with distilled water and dispersed into ethanol and further dispersed and mixed uniformly with conductive silver particles having a diameter of 3-5 μm to produce the conductive paste including 13 parts by weight of an epoxy resin, 1 part by weight of the carbon nanotubes, 84 parts by weight of silver particles and 2 parts by weight of a curing agent was obtained. The resulting conductive paste was cured at 168° C. and a specific resistance of the conductive paste was measured by Four-point probe. The result is shown in Table 2.

### Example 2

The multi-walled carbon nanotubes (provided by Iljin Limited) were immersed in the mixture of H₂SO₄ and HNO₃ (1:3) at 120° C. for 10 hours. The carbon nanotubes were washed with distilled water and dispersed into ethanol and further dispersed by the ultrasonic treatment and mixed uniformly with conductive silver particles having a diameter of 3-5 μm, to produce the conductive paste including 13 parts by weight of an epoxy resin, 1 part by weight of CNT, 84 parts by weight of silver particles and 2 parts by weight of a curing agent was obtained. The resulting conductive paste was cured at 168° C. and a specific resistance of the conductive paste was measured by Four-point probe. The result is shown in Table 2.

### Example 3

The multi-walled carbon nanotubes used in Example 2 were immersed in the mixture of H₂SO₄ and HNO₃ (1:3) at 120° C. for 10 hours. The carbon nanotubes were washed with distilled water and aged at room temperature for 72 hours. Then, the carbon nanotubes were immersed in an aqueous solution of 0.1M SnCl₂-0.1M HCl for 30 minutes and washed with distilled water. The carbon nanotubes were then immersed in an aqueous solution of 0.0014M PdCl₂-0.25M HCl to provide active sites for depositing silver particles on the surface of the carbon nanotubes. The activated carbon nanotubes were washed with distilled water and mixed with a solution of AgNO₃ 10 kg/m³ of pH 8.5 (HCHO was added as a silver catalyst) to provide silver-coated carbon nanotubes. The silver-coated carbon nanotubes were then washed with distilled water and dispersed into ethanol and further dispersed by the ultrasonic treatment and mixed with conductive silver particles having a diameter of 3-5 μm to provide the conductive paste including 13 parts by weight of an epoxy resin, 1 part by weight of carbon nanotubes coated with silver, 84 parts by weight of silver particles and 2 parts by weight of a curing agent was obtained. The resulting conductive paste was cured at 168° C. and a specific resistance of the conductive paste was measured by Four-point probe. The result is shown in Table 2.

### Comparative Example 1

A conductive paste including 84 parts by weight of silver particles having a diameter of 3-5 μm, 13 parts by weight of a epoxy resin, and 3 parts by weight of a curing agent was cured at 168° C. and a specific resistance of the conductive paste was measured by Four-point probe. The result is shown in Table 2.

### Comparative Example 2

Comparative Example 2 was conducted in the same manner as in Comparative Example 1 except that the conductive paste was diluted in ethanol.

TABLE 2

| | | | Specific Resistance |
|---|---|---|---|
| Category | | | (Ω · cm) |
| Examples | 1 | SWNTs + Silver paste | 6.0 × 10⁻⁵ |
| | 2 | MWNTs + Silver paste | 4.13 × 10⁻⁵ |
| | 3 | CNT coated with silver + Silver | 1.84 × 10⁻⁵ |
| | | paste | |
| Comparative | 1 | silver paste | 1 × 10⁻⁴ |
| Examples | 2 | silver paste diluted in ethanol | 7.32 × 10⁻⁵ |

From the results listed in Table 2, it can be seen that the specific resistances of Examples 1-3 are lowered, so that the electrical conductivity is improved.

While the spirit of the invention has been described in detail with reference to particular embodiments, the embodiments are for illustrative purposes only and do not limit the invention.

It is to be appreciated that those skilled in the art can change or modify the embodiments without departing from the scope and spirit of the invention.

What is claimed is:

1. A conductive paste comprising conductive particles; carbon nanotubes; and a binder.

2. The conductive paste of claim 1, wherein the surface of the carbon nanotubes are coated with metal particles.

3. The conductive paste of claim 2, the metal particles are selected from the group consisting of silver, copper, tin, indium, nickel, palladium, and mixtures thereof.

4. The conductive paste of claim 1, wherein the conductive paste comprises 70 to 90 parts by weight of the conductive particles, 0.5 to 15 parts by weight of the carbon nanotubes, and 1 to 15 parts by weight of the binder, per 100 parts by weight of the conductive paste.

5. The conductive paste of claim 1, wherein the carbon nanotubes are selected from the group consisting of single-walled carbon nanotubes, multi-walled carbon nanotubes and mixtures thereof.

6. The conductive paste of claim 1, wherein the conductive particles are selected from the group consisting of silver, copper, tin, indium, nickel and mixtures thereof.

7. The conductive paste of claim 1, wherein the conductive paste has a specific resistance of 5.0×10⁻⁴ to 3.0×10⁻⁶ Ω·cm after curing at a temperature range of about 140 to 200° C.

8. A printed circuit board comprising:
a plurality of substrates;
an insulation layer placed between the substrates; and
a conductive paste bump penetrating the insulation layer and interconnecting the substrate, wherein the conductive paste bump comprises conductive particles, carbon nanotubes, and a binder.

9. The printed circuit board of claim 8, wherein the surface of carbon nanotubes are coated with metal particles.

10. The printed circuit board of claim 9, wherein the metal particles are selected from the group consisting of silver, copper, tin, indium, nickel, palladium, and mixtures thereof.

11. The printed circuit board of claim 8, wherein the carbon nanotubes are selected from the group consisting of single-walled carbon nanotubes, multi-walled carbon nanotubes and mixtures thereof.

12. The printed circuit board of claim 8, wherein the conductive paste bump comprises 70 to 90 parts by weight of the conductive particles, 0.5 to 15 parts by weight of the carbon nanotubes, and 1 to 15 parts by weight of the binder, per 100 parts by weight of the conductive paste bump.

13. The printed circuit board of claim 8, wherein the conductive paste bump has a specific resistance of 5.0×10⁻⁴ to 3.0×10⁻⁶ Ω·cm after curing at a temperature range of about 140 to 200° C.
